(19) United States
(12) Patent Application Publication
(10) Pub. No.: US 2013/0168065 A1
(43) Pub. Date: Jul. 4, 2013

(54) FIXING DEVICE FOR FAN

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/403,926

(22) Filed: Feb. 23, 2012

(30) Foreign Application Priority Data
Dec. 29, 2011 (CN) 201110450122.7

(51) Int. Cl. H05K 7/20; H05K 5/00; F28F 13/06

(52) U.S. Cl. 165/122; 248/674; 248/639; 454/184

(57) ABSTRACT

A fixing device for fixing a fan includes a support and a number of fastening members. The fan includes two opposite sidewalls each defining a number of fixing holes. The support includes a fixing plate defining a vent area and a number of slots located around the vent area. Each fastening member includes a sleeve member and an inserting member. The sleeve member is inserted into the corresponding slot of the fixing plate and extended through the corresponding fixing hole of one of the sidewalls of the fan. The inserting member is extended through the corresponding fixing hole of the other sidewall of the fan, to engage with the sleeve. A first block protrudes from the sleeve to abut against the fixing plate. A second block protrudes from the inserting pole to abut against the other sidewall of the fan.

### BACKGROUND

1. Technical Field

The present disclosure relates to fixing devices, and particularly to a fixing device for a fan such as a fan used in a computer system.

2. Description of Related Art

In a typical computer system, one or more fans are secured by screws or the like to an enclosure of the computer system. The fans are used for producing airflow to dissipate heat from electrical components within the enclosure, thus keeping the components operating within a desired temperature range. However, as computer systems become smaller in size, the components are more tightly arranged within the enclosure of the computer system. When the fans are secured to or removed from the enclosure, use of a screwdriver for screwing or unscrewing the screws may cause damage to the components, as there is not enough space for the screwdriver within the enclosure of the computer system. In addition, the installation or removal of the screws is time consuming and troublesome.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is an exploded, isometric view of part of an electronic device which employs an exemplary embodiment of a fixing device, wherein the fixing device includes an L-shaped support and a plurality of fixing members.

FIG. 2 is an enlarged view of one of the fixing members of FIG. 1.

FIG. 3 is an assembled view of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references can mean “at least one.”

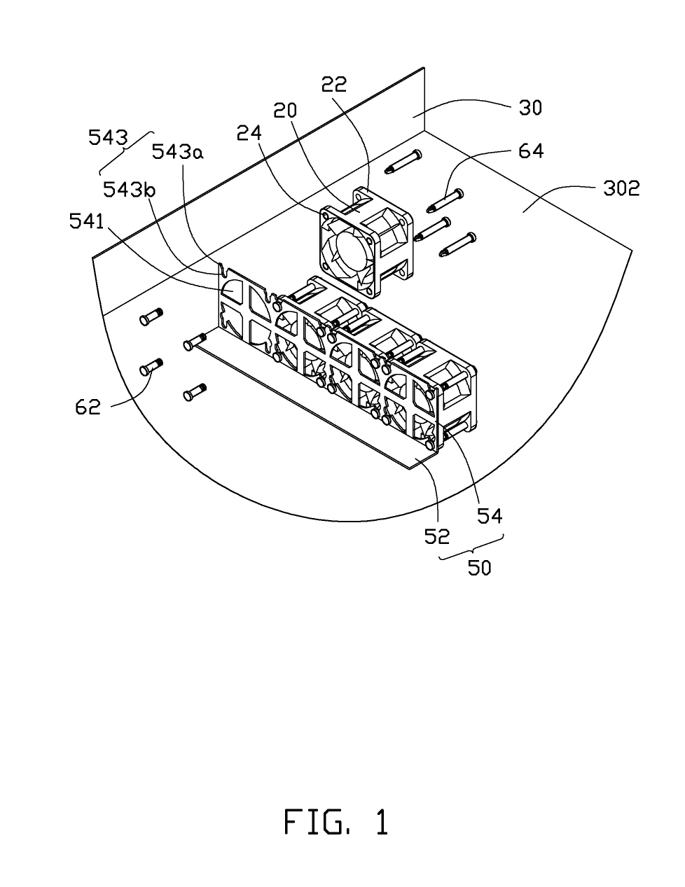

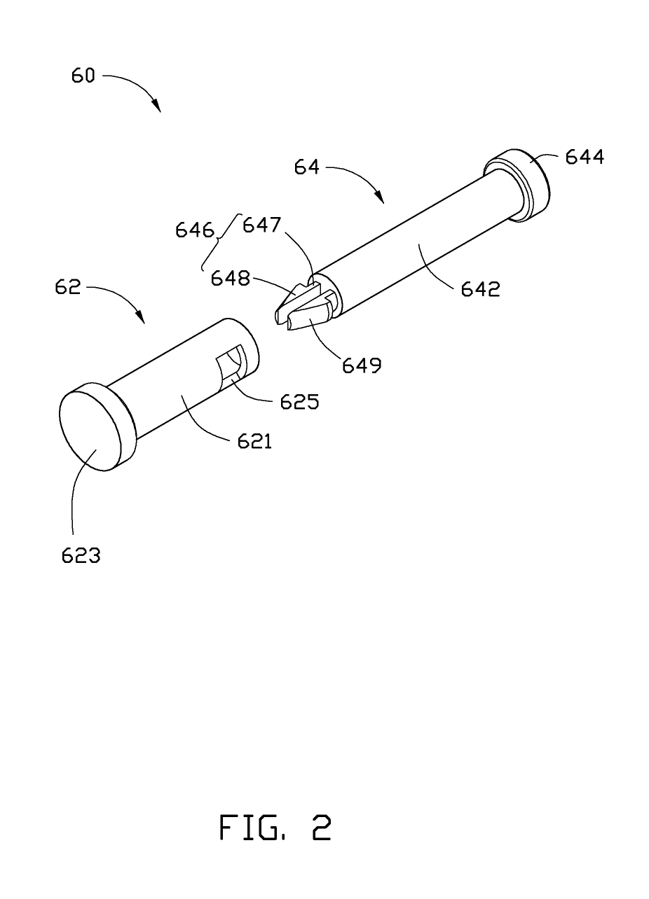

Referring to FIGS. 1 and 2, aspects of an exemplary embodiment of a fixing device are shown. The fixing device is used for fixing one or more fans 20 in an electronic device 30. Each fan 20 includes two opposite sidewalls 22. Four corners of each sidewall 22 each define a fixing hole 24. The electronic device 30 includes a bottom wall 302. The fixing device includes an L-shaped support 50 and a plurality of fastening members 60.

The support 50 includes a mounting plate 52 secured to the bottom wall 302, and a fixing plate 54 perpendicularly extending up from the mounting plate 52. A plurality of vent areas 541 is defined in the fixing plate 54, with the vent areas 541 aligned along the lengthwise direction of the fixing plate 54. Each vent area 541 includes a plurality of through holes. The fixing plate 54 defines a plurality of slots 543, each slot 543 being adjacent to a respective corner of a respective vent area 541. Each slot 543 at each top corner of each of the vent areas 541 includes a guiding portion 543a extending through the top edge of the fixing plate 54, and a holding portion 543b extending down from a bottom end of the guiding portion 543a. Each slot 543 at each bottom corner of each of the vent areas 541 is similar to each slot 543 at each top corner of each of the vent areas 541, and includes a guiding portion 543a communicating with a corresponding one of the through holes of the vent area 541, and a holding portion 543b extending down from a bottom end of the guiding portion 543a. A width of each guiding portion 543a is larger than a width of the corresponding holding portion 543b.

Each fastening member 60 includes a sleeve member 62 and an inserting member 64. The sleeve member 62 includes a hollow cylinder 621 and a block 623 protruding out from a first end of the cylinder 621. The circumferential wall of the cylinder 621 defines two opposite latching holes 625, both adjacent to a second end of the cylinder 621 that is opposite to the first end. The inserting member 64 includes a connecting pole 642, a block 644 protruding out from a first end of the connecting pole 642, and two opposite resilient hooks 646 extending out from a second end of the connecting pole 642 that is opposite to the first end. Each hook 646 includes a resilient extending portion 647 extending out from the connecting pole 642, and a wedge-shaped protrusion 648 extending out from a distal end of the extending portion 647. An outer surface of each protrusion 648 forms a slanted guiding surface 649. The two slanted guiding surfaces 649 are oriented symmetrically opposite relative to each other, such that the two protrusions 648 can be considered to extend away from each other in mutually opposite directions.

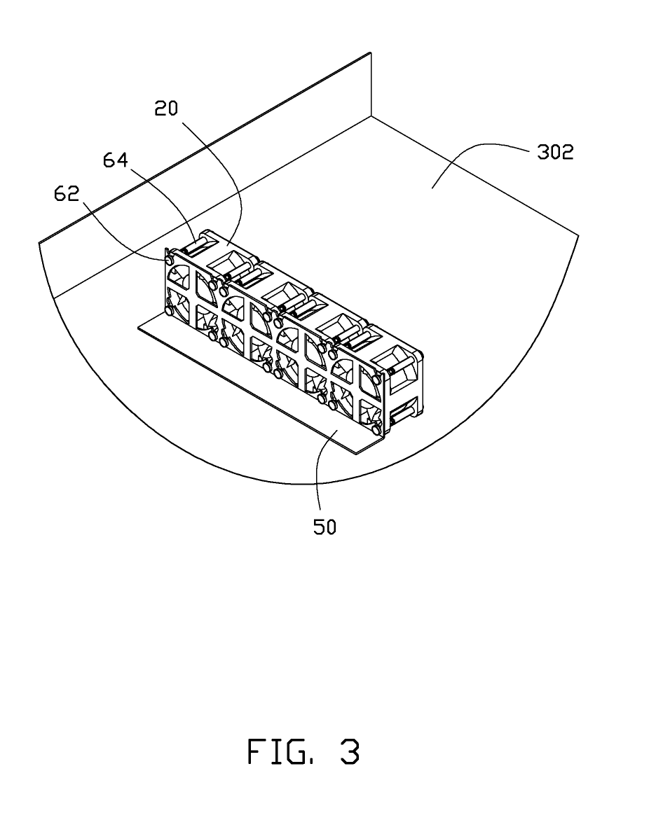

Referring also to FIG. 3, in assembly of four fastening members 60 to each fan 20, the cylinder 621 of each inserting member 64 is inserted into a corresponding fixing hole 24 from an outer side of one of the sidewalls 22. The connecting pole 642 of the inserting member 64 is inserted into a corresponding fixing hole 24 from an outer side of the other sidewall 22. The guiding surfaces 649 of the hooks 646 ride along an inner surface of the cylinder 621, and the hooks 646 are elastically deformed toward each other. When the hooks 646 become aligned with the corresponding latching holes 625, the hooks 646 self-restore and snappingly engage in the corresponding latching holes 625. When the four fastening members 60 are attached to the fan 20, the fan 20 is located between the blocks 623 of the sleeve members 62 and the blocks 644 of the inserting members 64. A distance between each of the blocks 623 of the sleeve members 62 and the neighboring sidewall 22 is substantially equal to a thickness of the fixing plate 54.

The combination of the fan 20 and the fastening members 60 is attached to the L-shaped support 50 as follows. Ends of the cylinders 621 adjacent to the blocks 623 are inserted into the holding portions 543b of the corresponding slots 543 via the corresponding guiding portions 543a. The blocks 644 abut against the corresponding sidewall 22 of the fan 20. The blocks 623 abut against an outer surface of the fixing plate 54 distant from the fan 20. The fan 20 is thus securely sandwiched between the blocks 644 and the fixing plate 54, and is aligned with a corresponding vent area 541.

The combination of the fan 20 and the fastening members 60 is detached from the L-shaped support 50 by disengaging the ends of the cylinders 621 adjacent to the blocks 623 from the corresponding slots 543. Then the combination of the fan 20 and the fastening members 60 can be easily removed from the fixing plate 54.

While the disclosure describes examples and embodiments, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A fixing device for fixing a fan thereon, the fan comprising a first sidewall and a second sidewall opposite to the first sidewall, and each of the first sidewall and the second sidewall defining a plurality of fixing holes, the fixing device comprising:
a support comprising a fixing plate, the fixing plate defining a vent area and a plurality of slots located around the vent area; and
a plurality of fastening members, each fastening member comprising a sleeve member and an inserting member, wherein the sleeve member is detachably inserted into a corresponding slot of the fixing plate and extends through a corresponding fixing hole of the first sidewall of the fan, the inserting member extends through a corresponding fixing hole of the second sidewall of the fan and is detachably engaged with the sleeve, the sleeve member comprises an enlarged first block at an end thereof, the first block abuts against an outer surface of the fixing plate distant from the fan, the inserting member comprises an enlarged second block at an end thereof, and the second block abuts against an outer surface of the second sidewall of the fan.

2. The fixing device of claim 1, wherein each slot above the vent area comprises a first guiding portion extending through a top edge of the fixing plate, and a first holding portion extending down from a bottom end of the first guiding portion, each slot below the vent area comprises a second guiding portion communicating with the vent area and a second holding portion extending down from a bottom end of the second guiding portion, and each sleeve member is detachably inserted into the corresponding one of the first or second holding portions via the corresponding first or second guiding portion.

3. The fixing device of claim 2, wherein each sleeve member comprises a hollow cylinder extending through the corresponding fixing hole of the first sidewall of the fan, the first block protrudes out from a first end of the cylinder, and the cylinder is inserted into the corresponding one of the first or second holding portions.

4. The fixing device of claim 3, wherein a second end of the cylinder opposite to the first block defines two latching holes, each inserting member comprises a connecting pole inserted into the corresponding fixing hole of the second sidewall of the fan, and two resilient hooks extending out from a first end of the connecting pole to engage in the latching holes of the corresponding cylinder, and the second block protrudes out from a second end of the connecting pole opposite to the hooks to abut against the outer surface of the second sidewall of the fan.

5. The fixing device of claim 4, wherein each hook comprises a resilient extending portion extending out from the connecting pole and a protrusion protruding out from a distal end of the extending portion to engage in a corresponding latching hole of the corresponding cylinder.

6. The fixing device of claim 5, wherein each protrusion is wedge-shaped, and an outer surface of the protrusion forms a slanted guiding surface.

7. The fixing device of claim 1, wherein the portion of the sleeve member of each fastening member detachably inserted into the corresponding slot of the fixing plate is adjacent to the first block.

8. The fixing device of claim 1, wherein the support further comprises a mounting plate adjacent to the fixing plate for mounting the support to an electronic device.

9. A fixing device for fixing a plurality of fans thereon, each fan comprising a first sidewall and a second sidewall opposite to the first sidewall, and each of the first sidewall and the second sidewall defining a plurality of fixing holes, the fixing device comprising:
a support comprising a fixing plate, the fixing plate defining a plurality of vent areas and a plurality of slots located around each vent area; and
a plurality of fastening members, each fastening member comprising a sleeve member and an inserting member, wherein the sleeve member is detachably inserted into a corresponding slot of the fixing plate and extends through a corresponding fixing hole of the first sidewall of the fan, the inserting member extends through a corresponding fixing hole of the second sidewall of the fan and is detachably engaged with the sleeve, the sleeve member comprises an enlarged first block at an end thereof, the first block abuts against an outer surface of the fixing plate distant from the fan, the inserting member comprises an enlarged second block at an end thereof, and the second block abuts against an outer surface of the second sidewall of the fan.

10. The fixing device of claim 9, wherein each slot above each vent area comprises a first guiding portion extending through a top edge of the fixing plate, and a first holding portion extending down from a bottom end of the first guiding portion, each slot below each vent area comprises a second guiding portion communicating with the corresponding vent area and a second holding portion extending down from a bottom end of the second guiding portion, and each sleeve member is detachably inserted into the corresponding one of the first or second holding portions via the corresponding first or second guiding portion.

11. The fixing device of claim 10, wherein each sleeve member comprises a hollow cylinder extending through the corresponding fixing hole of the first sidewall of the corresponding fan, the first block protrudes out from a first end of the cylinder, and the cylinder is inserted into the corresponding one of the first or second holding portions.

12. The fixing device of claim 11, wherein a second end of the cylinder opposite to the first block defines two latching holes, each inserting member comprises a connecting pole inserted into the corresponding fixing hole of the second sidewall of the corresponding fan, and two resilient hooks extending out from a first end of the connecting pole to engage in the latching holes of the corresponding cylinder, and the second block protrudes out from a second end of the connecting pole opposite to the hooks to abut against the outer surface of the second sidewall of the fan.

13. The fixing device of claim 12, wherein each hook comprises a resilient extending portion extending out from the connecting pole and a protrusion protruding out from a distal end of the extending portion to engage in a corresponding latching hole of the corresponding cylinder.

14. The fixing device of claim 13, wherein each protrusion is wedge-shaped, and an outer surface of the protrusion forms a slanted guiding surface.

15. The fixing device of claim 9, wherein the portion of the sleeve member of each fastening member detachably inserted into the corresponding slot of the fixing plate is adjacent to the first block.

16. The fixing device of claim 9, wherein the support further comprises a mounting plate adjacent to the fixing plate for mounting the support to an electronic device.

17. A fan assembly comprising:
a plurality of fans, each fan comprising a first sidewall and a second sidewall opposite to the first sidewall, and each of the first sidewall and the second sidewall defining a plurality of fixing holes;
a support comprising a fixing plate, the fixing plate defining a plurality of vent areas and a plurality of slots located around each vent area; and
a plurality of fastening members, each fastening member comprising a sleeve member and an inserting member, wherein the sleeve member is detachably inserted into a corresponding slot of the fixing plate and extends through a corresponding fixing hole of the first sidewall of the fan, the inserting member extends through a corresponding fixing hole of the second sidewall of the fan and is detachably engaged with the sleeve, the sleeve member comprises an enlarged first block at an end thereof, the first block abuts against an outer surface of the fixing plate distant from the fan, the inserting member comprises an enlarged second block at an end thereof, and the second block abuts against an outer surface of the second sidewall of the fan.

18. The fan assembly of claim 17, wherein each slot above each vent area comprises a first guiding portion extending through a top edge of the fixing plate, and a first holding portion extending down from a bottom end of the first guiding portion, each slot below each vent area comprises a second guiding portion communicating with the corresponding vent area and a second holding portion extending down from a bottom end of the second guiding portion, and each sleeve member is detachably inserted into the corresponding one of the first or second holding portions via the corresponding first or second guiding portions.

19. The fan assembly of claim 18, wherein each sleeve member comprises a hollow cylinder extending through the corresponding fixing hole of the first sidewall of the corresponding fan, the first block protrudes out from a first end of the cylinder, and the cylinder is inserted into the corresponding one of the first or second holding portions.

20. The fan assembly of claim 19, wherein a second end of the cylinder opposite to the first block defines two latching holes, each inserting member comprises a connecting pole inserted into the corresponding fixing hole of the second sidewall of the corresponding fan, and two resilient hooks extending out from a first end of the connecting pole to engage in the latching holes of the corresponding cylinder, and the second block protrudes out from a second end of the connecting pole opposite to the hooks to abut against the outer surface of the second sidewall of the fan.
